(19) United States
(12) Patent Application Publication
(10) Pub. No.: US 2022/0179310 A1
(43) Pub. Date: Jun. 9, 2022

(54) BISMALEIMIDE COMPOUND, PHOTOSENSITIVE RESIN COMPOSITION USING SAME, CURED PRODUCT THEREOF, AND SEMICONDUCTOR ELEMENT

(71) Applicant: NIPPON KAYAKU KABUSHIKI KAISHA, Tokyo (JP)

(72) Inventors: Kazuyoshi YAMAMOTO, Tokyo (JP); Nobuhiko NAITOU, Tokyo (JP); Taiki KAGA, Tokyo (JP); Mai TSUBAMOTO, Tokyo (JP)

(73) Assignee: NIPPON KAYAKU KABUSHIKI KAISHA, Tokyo (JP)

(21) Appl. No.: 17/600,381

(22) PCT Filed: Mar. 27, 2020
(86) PCT No.: PCT/JP2020/014181

§ 371 Date: Sep. 30, 2021

(30) Foreign Application Priority Data
Apr. 2, 2019 (JP) 2019-070316

(51) Int. Cl. G03F 7/031; C08G 73/12

(52) U.S. Cl. CPC G03F 7/031; H01L 23/293; C08G 73/12

(57) ABSTRACT

A bismaleimide compound (I) having a cyclic imide bond, which is obtained by a reaction of a diamine (A) derived from a dimer acid, a tetracarboxylic dianhydride (C) having an alicyclic structure, and maleic anhydride.

### TECHNICAL FIELD

The present invention relates to a bismaleimide compound, a photosensitive resin composition using the same, a cured product thereof, and a semiconductor element. The photosensitive resin composition of the present invention can be applied to a protective film for a semiconductor element, an interlayer insulating film, an insulating film of a rewiring layer, and the like.

### BACKGROUND ART

Hitherto, for a protective film for a semiconductor element, an interlayer insulating film formed on a semiconductor surface layer, and an insulating film of a rewiring layer, there is used a photosensitive resin composition containing a polyimide precursor or a polybenzoxazole precursor, which is excellent in heat resistance, electrical properties, and mechanical properties. As the photosensitive resin composition containing a polyimide precursor, for example, JP-A-S54-109828 (Patent Literature 1) describes a resin composition containing a polyamic acid, a compound having a polymerizable unsaturated bond, and a photopolymerization initiator. Further, JP-A-2008-83468 (Patent Literature 2) describes a resin composition containing a polyamic acid ester composition and a photopolymerization initiator. The photosensitive polyimide precursors obtained in such resin compositions are negative type photosensitive materials in which a pattern can be obtained by photocrosslinking unsaturated bond(s) by the action of a photopolymerization initiator. Moreover, as the photosensitive resin composition containing a polybenzoxazole precursor, for example, JP-A-S56-27140 (Patent Literature 3) and JP-A-H11-237736 (Patent Literature 4) describe resin compositions each containing a polybenzoxazole precursor and a quinonediazide compound. Such resin compositions are positive photosensitive materials in which a portion (exposed portion) irradiated with light is dissolved in an alkaline developing solution through conversion of a quinonediazide into an indenecarboxylic acid by light irradiation and thus a pattern is obtained.

Since the polyimide precursors and the polybenzoxazole precursors as described in Patent Literatures 1 to 4 need to undergo a dehydration ring-closure reaction in the curing reaction, it is necessary to heat them to a temperature exceeding at least 230° C. in order to achieve curing. However, when the heating temperature is high as above, the semiconductor element may be damaged, and also, since the linear thermal expansion coefficient differs between the substrate such as a silicon wafer and the film made of the photosensitive resin composition, there is a problem that residual stress is generated in the film after curing owing to the temperature difference until it is cooled to room temperature. Furthermore, in the photosensitive resin compositions as described in Patent Literatures 1 to 4, the polymer skeleton of the resin obtained by curing is set to a skeleton composed of a rigid aromatic compound for the purpose of improving the heat resistance and mechanical properties. Therefore, the tensile elastic modulus after curing becomes high and there are problems that the adhesion to an adherend is lowered and the residual stress is further increased. Such residual stress causes warpage of the substrate such as a silicon wafer, and causes inconveniences such as a decrease in joint reliability with an interposer in flip chip mounting and the like and a decrease in handling ability of the substrate such as a silicon wafer in a semiconductor manufacturing process. Particularly, in recent years, with the progress of a decrease in the thickness of a silicon wafer from the viewpoint of miniaturization and thinning of semiconductor elements and an increase in the diameter of a silicon wafer from the viewpoint of improving mass productivity (about 300 mm diameter at mass production level, about 450 mm diameter in the future), the problem on such residual stress becomes more serious.

In addition, as a photosensitive resin composition for the purpose of lowering the temperature for curing (curing temperature), JP-A-2009-258433 (Patent Literature 5) and JP-A-2009-175356 (Patent Literature 6) describe resin compositions each containing a polybenzoxazole precursor. Moreover, as another photosensitive resin composition, for example, JP-A-2010-256532 (Patent Literature 7) describes a photosensitive resin composition containing an amine compound derived from a dimer acid and a polyamic acid to be obtained by a condensation reaction of a diamine with a tetracarboxylic dianhydride. Further, JP-T-2006-526014 (Patent Literature 8) describes a polymaleinimide compound in which an amic acid structure is ring-closed in advance and a maleimide group is introduced as a polymerizable functional group, and a photosensitive resin composition containing the polymaleinimide compound is described in US Patent Application Publication No. 2011/0049731 (Patent Literature 9).

### CITATION LIST

### Patent Literature

Patent Literature 1: JP-A-S54-109828
Patent Literature 2: JP-A-2008-83468
Patent Literature 3: JP-A-S56-27140
Patent Literature 4: JP-A-H11-237736
Patent Literature 5: JP-A-2009-258433
Patent Literature 6: JP-A-2009-175356
Patent Literature 7: JP-A-2010-256532
Patent Literature 8: JP-T-2006-526014
Patent Literature 9: US Patent Application Publication No. 2011/0049731

### SUMMARY OF INVENTION

### Problem to be Solved by Invention

Since a polyimide precursor and a polybenzoxazole precursor have a large absorption at 436 nm and 365 nm, in the case of using a reduction projection exposure machine (stepper; light source wavelength: 365 nm, 436 nm) used as a standard in the manufacturing process of a semiconductor protective film or the like, the present inventors have found that, as the film thickness increases, the light reaching the bottom decreases and thus it becomes difficult to form a pattern. In particular, the film thickness of the protective film for semiconductor elements or the like is generally 5 μm or less, but there are many portions where the film thickness is actually 10 μm or more owing to unevenness caused by wiring. In such portions, there is a problem that sufficient patterning performance is not exhibited and chip design is restricted.

Moreover, the polyamic acid described in Patent Literature 7 has a polyamic acid structure obtained from an amine compound (dimer diamine) derived from a dimer acid and a tetracarboxylic dianhydride, and it is expected that a cured product excellent in flexibility is obtained. However, since the polyamic acid described in Patent Literature 7 does not have a photopolymerizable functional group, it is necessary to add a photopolymerizable compound to the resin composition. For example, when a polyfunctional polymerizable compound having a plurality of polymerizable functional groups such as an acrylic compound, which is common as a photopolymerizable compound, is used together with the polyamic acid, there is a problem that a crosslinking reaction by photopolymerization proceeds and the tensile elastic modulus after curing increases. Furthermore, since the photosensitive resin composition described in Patent Literature 7 needs to undergo a dehydration ring-closure reaction of an amic acid structure in a curing reaction, heating at a high temperature of more than 230° C. is necessary and thus there is also a problem that residual stress that causes warpage of a substrate such as a silicon wafer is generated.

In addition, since the polymaleinimide compound described in Patent Literature 8 is a soluble imide oligomer, the resin composition described in Patent Literature 9 containing this compound can be cured at a relatively low temperature. However, when the resin composition described in Patent Literature 9 is used, there are a problem that the adhesion to the inorganic surface protective film (passivation film) such as a SiN film or a SiO₂ film formed on a silicon wafer or a chip or a conductive metal wiring material (copper or the like) is remarkably lowered and a problem that it is difficult to form a fine pattern. Further, as a method for improving the adhesion, there may be mentioned a method of improving the efficiency of the crosslinking reaction through photopolymerization by increasing the exposure amount. However, since the polymaleinimide compound described in Patent Literature 8 requires an extremely large exposure amount as compared with an acrylic compound or the like usually used as a photopolymerizable compound, there is a problem that productivity is lowered in the semiconductor manufacturing process. Furthermore, as a method of reducing the residual stress in the film after curing and improving the patterning performance, a method of reducing the film thickness may be mentioned. However, when the film thickness is reduced, there is a problem that the intrinsic insulating property as a protective film for a semiconductor element or an insulating film is impaired.

The present invention has been made in view of the above-described problems of the background art. An object of the present invention is to provide a bismaleimide compound that is capable of forming a fine pattern at a relatively low exposure amount, does not require conventional heat-curing at a high temperature, and can afford a cured product having a sufficiently small tensile elastic modulus and exhibiting an excellent adhesion to an inorganic surface protective film or a metal wiring material, a photosensitive resin composition using the same, a cured product thereof, and a semiconductor element including the cured product.

### Means for Solving Problem

As a result of intensive studies to achieve the above object, the present inventors have found that, by using a photosensitive resin composition containing a specific bismaleimide compound (I), a fine pattern can be formed at a relatively low exposure amount and heat-curing is not required or, even when the heat-curing is performed as needed, conventional heat-curing at a high temperature is not required. Furthermore, they have found that the cured product obtained by using such a photosensitive resin composition has a sufficiently small tensile elastic modulus, exhibits an excellent adhesion to an inorganic surface protective film or a metal wiring material, and thus, for example, can be particularly suitably used as a surface protective film of a semiconductor element, an interlayer insulating film, an insulating film of a rewiring layer, etc., for which it is necessary to maintain high insulating properties. Thus, they have completed the present invention.

That is, the present invention relates to:

[1] A bismaleimide compound (I) having a cyclic imide bond, which is obtained by a reaction of a diamine (A) derived from a dimer acid, a tetracarboxylic dianhydride (C) having an alicyclic structure, and maleic anhydride;
[2] The bismaleimide compound (I) according to [1], which is obtained by a reaction of the diamine (A), the tetracarboxylic dianhydride (C), the maleic anhydride, and, in addition, an organic diamine (B) other than the diamine (A) derived from the dimer acid;
[3] The bismaleimide compound (I) according to [1] or [2], wherein the bismaleimide compound (I) is represented by the following general formula (1):

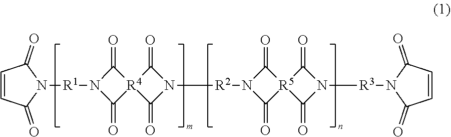

wherein R¹ represents a divalent hydrocarbon group (a) derived from a dimer acid, R² represents a divalent organic group (b) other than the divalent hydrocarbon group (a) derived from the dimer acid, R³ represents any one selected from the group consisting of the divalent hydrocarbon group (a) derived from the dimer acid and the divalent organic group (b) other than the divalent hydrocarbon group (a) derived from the dimer acid, and R⁴ and R⁵ represent each independently one or more organic groups selected from a tetravalent organic group having 4 to 40 carbon atoms which has a monocyclic or condensed polycyclic alicyclic structure, a tetravalent organic group having 8 to 40 carbon atoms in which organic groups each having a monocyclic alicyclic structure are linked to each other directly or via a crosslinking structure, and a tetravalent organic group having 8 to 40 carbon atoms which has a semi-alicyclic structure having both an alicyclic structure and an aromatic ring; m is an integer of 1 to 30, n is an integer of 0 to 30, and R⁴ and R⁵ may be the same or different from each other;
[4] The bismaleimide compound (I) according to any one of [1] to [3], wherein the tetracarboxylic dianhydride (C) is represented by the general formula (2):

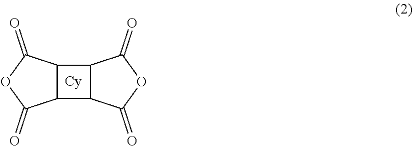

wherein Cy is a tetravalent organic group having 4 to 40 carbon atoms which contains a hydrocarbon ring and the organic group may contain an aromatic ring;
[5] The bismaleimide compound according to [4], wherein the Cy is selected from the group consisting of the formulae (3-1) to (3-11):

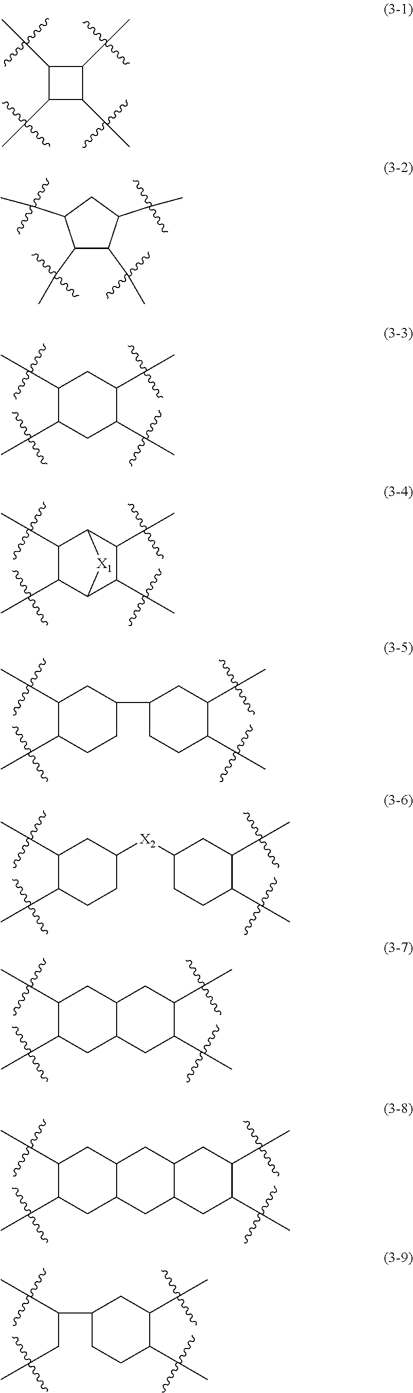

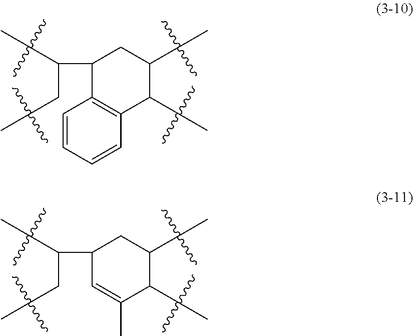 [SMILES: *CC(*)C1CC(*)C(*)c2ccccc21 ; *CC(*)C1C=C(C)C(*)C(*)C1]

in the general formula (3-4), X₁ is a direct bond, an oxygen atom, a sulfur atom, a sulfonyl group, or a divalent organic group having 1 to 3 carbon atoms; in the general formula (3-6), X₂ is a direct bond, an oxygen atom, a sulfur atom, a sulfonyl group, a divalent organic group having 1 to 3 carbon atoms, or an arylene group;

[6] The bismaleimide compound (I) according to any one of [1] to [4], wherein the tetracarboxylic dianhydride (C) is one or more selected from 1,2,3,4-cyclobutanetetracarboxylic dianhydride (CBDA), 1,2-dimethyl-1,2,3,4-cyclobutanetetracarboxylic dianhydride, 1,2,3,4-tetramethyl-1,2,3,4-cyclobutanetetracarboxylic dianhydride, 1,2,3,4-cyclopentanetetracarboxylic dianhydride, 1,2,4,5-cyclohexanetetracarboxylic dianhydride (H-PMDA), 1,1′-bicyclohexane-3,3′,4,4′-tetracarboxylic-3,4:3′, 4′-dianhydride (H-BPDA), 4-(2,5-dioxotetrahydrofuran-3-yl)-1,2,3,4-tetrahydronaphthalene-1,2-dicarboxylic anhydride, 5-(2, 5-dioxotetrahydrofuryl)-3-methyl-3-cyclohexene-1,2-dicarboxylic dianhydride, bicyclo[2.2.2]oct-7-ene-2,3,5,6-tetracarboxylic dianhydride, 2,3,4,5-tetrahydrofuranetetracarboxylic dianhydride, and 3,5,6-tricarboxy-2-norbornaneacetic dianhydride;
[7] The bismaleimide compound (I) according to any one of [1] to [6], wherein the tetracarboxylic dianhydride (C) is a compound of the following formula (4);

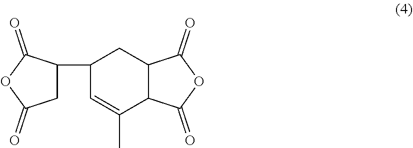 [SMILES: CC1=CC(C2CC(=O)OC2=O)CC2C(=O)OC(=O)C12]

[8] The bismaleimide compound (I) according to any one of [1] to [6], wherein the tetracarboxylic dianhydride (C) is a compound of the following formula (5);

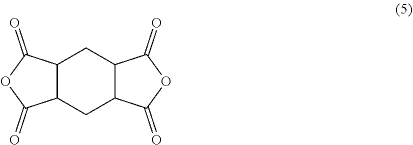 [SMILES: O=C1OC(=O)C2CC3C(=O)OC(=O)C3CC12]

[9] The bismaleimide compound (I) according to any one of [1] to [6], wherein the tetracarboxylic dianhydride (C) is a compound of the following formula (6);

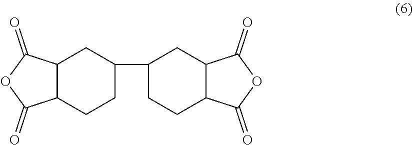 [SMILES: O=C1OC(=O)C2CC(C3CCC4C(=O)OC(=O)C4C3)CCC12]

[10] The bismaleimide compound (I) according to any one of [1] to [6], wherein the tetracarboxylic dianhydride (C) is a compound of the following formula (7);

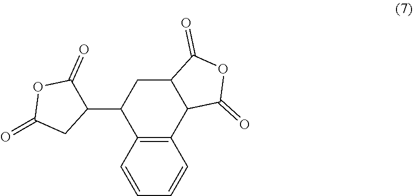 [SMILES: O=C1CC(C2CC3C(=O)OC(=O)C3c3ccccc32)C(=O)O1]

[11] A photosensitive resin composition containing the bismaleimide compound (I) according to any one of [1] to [10] and a photopolymerization initiator (II), wherein the photopolymerization initiator (II) is a compound having an oxime structure or a thioxanthone structure;
[12] The photosensitive resin composition according to [11], wherein the content of the photopolymerization initiator (II) is 0.1 to 15 parts by mass with respect to 100 parts by mass of the bismaleimide compound (I);
[13] A cured product obtained by photo-curing or photo- and heat-curing of the photosensitive resin composition according to [11] or [12]; and
[14] A semiconductor element including the cured product according to [13] as at least one selected from the group consisting of a surface protective film, an interlayer insulating film, and an insulating film of a rewiring layer.

### Advantageous Effects of Invention

According to the present invention, it is possible to provide a bismaleimide compound that is capable of forming a fine pattern at a low exposure amount, does not require conventional heat-curing at a high temperature and can afford a cured product having a sufficiently small tensile elastic modulus and exhibiting an excellent adhesion to an inorganic surface protective film or a metal wiring material, a photosensitive resin composition using the same, a cured product thereof, and a semiconductor element including the cured product.

### MODES FOR CARRYING OUT INVENTION

Hereinafter, the present invention will be described in detail according to preferred embodiments thereof.

### <Bismaleimide Compound (I)>

The bismaleimide compound (I) according to the present invention is a compound having two maleimide groups, and has a divalent hydrocarbon group (a) derived from a dimer acid and a cyclic imide bond. Such a bismaleimide compound (I) can be obtained by a reaction of a diamine (A) derived from a dimer acid, a tetracarboxylic dianhydride (C) having an alicyclic structure, and maleic anhydride.

The divalent hydrocarbon group (a) derived from the dimer acid refers to a divalent residue obtained by removing two carboxyl groups from the dicarboxylic acid contained in the dimer acid. In the present invention, such a divalent hydrocarbon group (a) derived from the dimer acid can be introduced into the bismaleimide compound by reacting a diamine (A), which is obtained by substituting two carboxyl groups of the dicarboxylic acid contained in the dimer acid with an amino group, with the tetracarboxylic dianhydride (C) and maleic anhydride, which will be described later, to form an imide bond.

In the present invention, the dimer acid is preferably a dicarboxylic acid having 20 to 60 carbon atoms. Specific examples of the dimer acid include those each obtained by dimerizing the unsaturated bond(s) of unsaturated carboxylic acid(s) such as linoleic acid, oleic acid, or linolenic acid, and then purifying the product by distillation. The dimer acid according to the above specific examples mainly contains dicarboxylic acid(s) having 36 carbon atoms, and usually contains tricarboxylic acid(s) having 54 carbon atoms in an amount of about 5% by mass at most and monocarboxylic acid(s) in an amount of about 5% by mass at most. The diamine (A) derived from the dimer acid according to the present invention (hereinafter, sometimes referred to as dimer acid-derived diamine (A)) is a diamine obtained by substituting two carboxyl groups of each dicarboxylic acid contained in the dimer acid with an amino group, and is usually a mixture. In the present invention, examples of such a dimer acid-derived diamine (A) include diamines such as [3,4-bis(1-aminoheptyl) 6-hexyl-5-(1-octenyl)]cyclohexane, and those containing diamines in which unsaturated bond(s) are saturated by further hydrogenating the above diamines.

As the divalent hydrocarbon group (a) derived from the dimer acid according to the present invention to be introduced into the bismaleimide compound using such a dimer acid-derived diamine (A) is preferably a residue obtained by removing two amino groups from the dimer acid-derived diamine (A). Further, when the bismaleimide compound (I) according to the present invention is obtained by using the dimer acid-derived diamine (A), as the dimer acid-derived diamine (A), one kind may be used alone or two or more kinds having different compositions may be used in combination. In addition, as such a dimer acid-derived diamine (A), a commercially available product such as “PRIAMINE 1074” (manufactured by Croda Japan K.K.) may be used.

In the present invention, the tetracarboxylic dianhydride (C) has an alicyclic structure adjacent to the anhydride group, and is a tetracarboxylic dianhydride having a structure such that, when a bismaleimide compound is formed after the reaction, the imide ring-adjacent portion has an alicyclic structure. When the imide ring-adjacent portion has an alicyclic structure, an aromatic ring may be additionally contained in the structure.

In the present invention, the bismaleimide compound (I) preferably has the following general formula (1). In the general formula (1), R⁴ and R⁵ are structures derived from the tetracarboxylic dianhydride (C).

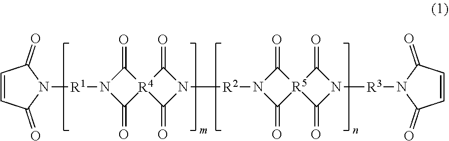

wherein R¹ represents a divalent hydrocarbon group (a) derived from a dimer acid, R² represents a divalent organic group (b) other than the divalent hydrocarbon group (a) derived from the dimer acid, R³ represents any one selected from the group consisting of the divalent hydrocarbon group (a) derived from the dimer acid and the divalent organic group (b) other than the divalent hydrocarbon group (a) derived from the dimer acid, and R⁴ and R⁵ represent each independently one or more organic groups selected from a tetravalent organic group having 4 to 40 carbon atoms (preferably 6 to 40 carbon atoms) which has a monocyclic or condensed polycyclic alicyclic structure, a tetravalent organic group having 8 to 40 carbon atoms in which organic groups each having a monocyclic alicyclic structure are linked to each other directly or via a crosslinking structure, and a tetravalent organic group having 8 to 40 carbon atoms which has a semi-alicyclic structure having both an alicyclic structure and an aromatic ring; m is an integer of 1 to 30, n is an integer of 0 to 30, and R⁴ and R⁵ may be the same or different from each other.

In the present invention, the tetracarboxylic dianhydride (C) is preferably a tetracarboxylic dianhydride (C) having an alicyclic structure represented by the following general formula (2). The tetracarboxylic dianhydride (C) having an alicyclic structure represented by the following general formula (2) has an alicyclic structure adjacent to the anhydride group.

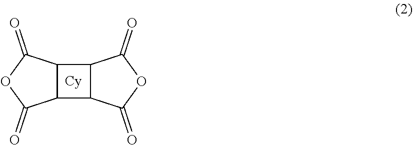

wherein Cy is a tetravalent organic group having 4 to 40 carbon atoms which contains a hydrocarbon ring and the organic group may contain an aromatic ring.

In the present invention, the tetracarboxylic dianhydride (C) is preferably a tetracarboxylic dianhydride (C) having an alicyclic structure represented by each of the following general formulae (3-1) to (3-11). The tetracarboxylic dianhydride (C) represented by each of the formulae (3-1) to (3-11) has a structure containing a tetravalent organic group having 4 to 40 carbon atoms (preferably 6 to 40 carbon atoms) which has a monocyclic or condensed polycyclic alicyclic structure, a tetravalent organic group having 8 to 40 carbon atoms in which organic groups each having a monocyclic alicyclic structure are linked to each other directly or via a crosslinking structure, and a tetravalent organic group having 8 to 40 carbon atoms which has a semi-alicyclic structure having both an alicyclic structure and an aromatic ring.

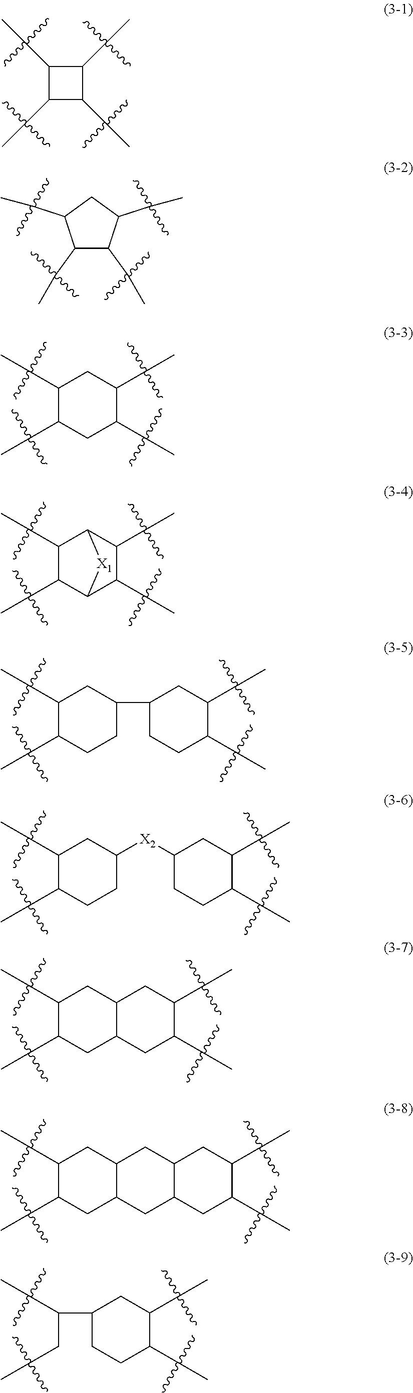

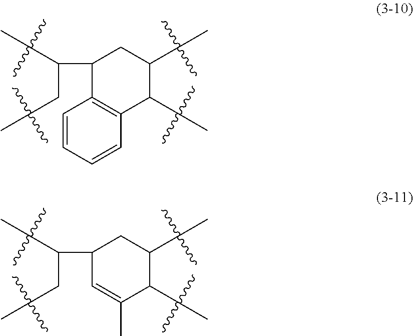

In the formula (3-4), X₁ is a direct bond, an oxygen atom, a sulfur atom, a sulfonyl group, or a divalent organic group having 1 to 3 carbon atoms. In the general formula (3-6), X₂ is a direct bond, an oxygen atom, a sulfur atom, a sulfonyl group, a divalent organic group having 1 to 3 carbon atoms, or an arylene group.

The tetracarboxylic dianhydride (C) to be used in the present invention preferably has a tetravalent organic group having 4 to 40 carbon atoms (preferably 6 to 40 carbon atoms) which has a monocyclic or condensed polycyclic alicyclic structure, a tetravalent organic group having 8 to 40 carbon atoms in which organic groups each having a monocyclic alicyclic structure are linked to each other directly or via a crosslinking structure, and a tetravalent organic group having 8 to 40 carbon atoms which has a semi-alicyclic structure having both an alicyclic structure and an aromatic ring. Specific examples of the tetracarboxylic dianhydride (C) having an alicyclic structure include alicyclic tetracarboxylic dianhydrides such as 1,2,3,4-cyclobutanetetracarboxylic dianhydride (CBDA), 1,2-dimethyl-1,2,3,4-cyclobutanetetracarboxylic dianhydride, 1,2,3,4-tetramethyl-1,2,3,4-cyclobutanetetracarboxylic dianhydride, 1,2,3,4-cyclopentanetetracarboxylic dianhydride, 1,2,4,5-cyclohexanetetracarboxylic dianhydride (H-PMDA), 1,1′-bicyclohexane-3,3′,4,4′-tetracarboxylic-3,4:3′,4′-dianhydride (H-BPDA), 4-(2,5-dioxotetrahydrofuran-3-yl)-1,2,3,4-tetrahydronaphthalene-1,2-dicarboxylic anhydride, 5-(2,5-dioxotetrahydrofuryl)-3-methyl-3-cyclohexene-1,2-dicarboxylic dianhydride, bicyclo[2.2.2]oct-7-ene-2,3,5,6-tetracarboxylic dianhydride, 2,3,4,5-tetrahydrofurantetracarboxylic dianhydride, and 3,5,6-tricarboxy-2-norbornaneacetic dianhydride or compounds obtained by substituting the aromatic rings of these alicyclic tetracarboxylic dianhydrides with an alkyl group or a halogen atom, and semi-alicyclic tetracarboxylic dianhydrides such as 1,3,3a,4,5,9b-hexahydro-5 (tetrahydro-2,5-dioxo-3-furanyl)naphtho[1,2-c]furan-1,3-dione or compounds obtained by substituting hydrogen atom(s) in the aromatic ring(s) of these semi-alicyclic tetracarboxylic dianhydrides with an alkyl group or a halogen atom.

Further, a pattern obtained from the photosensitive resin composition of the present invention preferably has a high resolution. The resolution means the minimum dimension obtained when a pattern is formed using the photosensitive resin composition, and the resolution is higher when a finer pattern can be formed.

In the present invention, the tetracarboxylic dianhydride (C) is preferably a tetracarboxylic dianhydride (C) having an alicyclic structure represented by the following general formula (4).

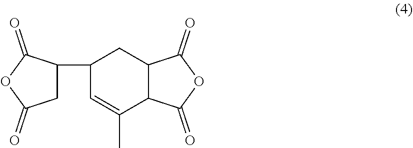

In the present invention, the tetracarboxylic dianhydride (C) is preferably a tetracarboxylic dianhydride (C) having an alicyclic structure represented by the following general formula (5).

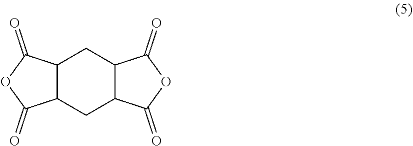

In the present invention, the tetracarboxylic dianhydride (C) is preferably a tetracarboxylic dianhydride (C) having an alicyclic structure represented by the following general formula (6).

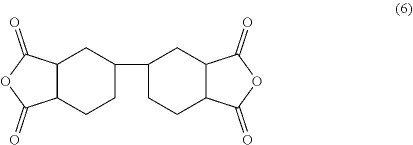

In the present invention, the tetracarboxylic dianhydride (C) is preferably a tetracarboxylic dianhydride (C) having an alicyclic structure represented by the following general formula (7).

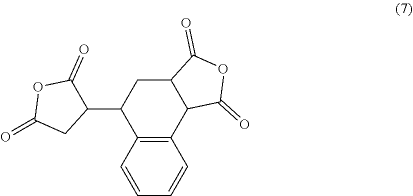

By using appropriate amounts of the tetracarboxylic dianhydride (C), the diamine (A) derived from a dimer acid, and maleic anhydride, a photosensitive resin composition having a high residual film ratio and a high sensitivity without tack and development residue during development can be obtained.

In the present invention, in addition to the tetracarboxylic dianhydride (C) having an alicyclic structure, an acid dianhydride having no alicyclic structure and an acid dianhydride containing an aromatic ring adjacent to the anhydride group may be added. The lower limit of the tetracarboxylic dianhydride (C) in the total amount of the acid dianhydride is preferably 40 mol % or more, more preferably 80 mol % or more, and particularly preferably 90 mol % or more. The upper limit may be 100 mol % or less. When the content of the tetracarboxylic dianhydride (C) in the total amount of the acid dianhydride is less than 40 mol %, the light condensing rate is low and a small pattern opening tends not to be obtained, so that there is a risk that the resolution of the pattern obtained decreases.

Specific examples of the acid dianhydride containing an aromatic ring adjacent to the anhydride group other than the tetracarboxylic dianhydride (C) include aromatic tetracarboxylic dianhydrides such as pyromellitic dianhydride, 4,4′-oxydiphthalic dianhydride, 3,3′,4,4′-biphenyltetracarboxylic dianhydride, 2,3,3′,4′-biphenyltetracarboxylic dianhydride, 2,2′,3,3′-biphenyltetracarcarboxylic dianhydride, 3,3′,4,4′-benzophenonetetracarboxylic dianhydride, 2,2′,3,3′-benzophenonetetracarboxylic dianhydride, 2,2-bis(3, 4-dicarboxyphenyl)propane dianhydride, 2,2-bis(2,3-dicarboxyphenyl)propane dianhydride, 1,1-bis(3,4-dicarboxyphenyl)ethane dianhydride, 1,1-bis(2,3-dicarboxyphenyl)ethane dianhydride, bis(3,4-dicarboxyphenyl)methane dianhydride, bis(2,3-dicarboxyphenyl)methane dianhydride, 1,2,5,6-naphthalenetetracarboxylic dianhydride, 2,3,6,7-naphthalenetetracarboxylic dianhydride, 2,3,5,6-pyridinetetracarboxylic dianhydride, and 3,4,9,10-perylenetetracarboxylic dianhydride, and aromatic acid dianhydrides such as bis(3,4-dicarboxyphenyl) sulfone dianhydride, bis(3,4-dicarboxyphenyl) ether dianhydride, 2,2-bis(3,4-dicarboxyphenyl)hexafluoropropane dianhydride or compounds obtained by substituting the aromatic ring(s) of these compounds with an alkyl group or a halogen atom, and acid dianhydrides having an amide group. They can be used in combination with acid dianhydrides having 4 to 40 carbon atoms and having an alicyclic structure or a semi-alicyclic structure as a combination of two or more kinds.

Furthermore, the bismaleimide compound (I) according to the present invention may be a bismaleimide compound obtained by a reaction of the dimer acid-derived diamine (A), the organic diamine (B) other than the dimer acid-derived diamine (A), the tetracarboxylic dianhydride (C), and the maleic anhydride. By copolymerizing the organic diamine (B) other than the dimer acid-derived diamine (A), it becomes possible to control the required physical properties, for example, further reduction of the tensile elastic modulus of the cured product to be obtained.

The organic diamine (B) other than the dimer acid-derived diamine (A) (hereinafter, sometimes simply referred to as organic diamine (B)) refers to a diamine other than the diamine included in the dimer acid-derived diamine (A) in the present invention. Such an organic diamine (B) is not particularly limited, and examples thereof include aliphatic diamines such as 1,6-hexamethylenediamine; alicyclic diamines such as 1,4-diaminocyclohexane and 1,3-bis(aminomethyl)cyclohexane; aromatic diamines such as 4,4′-diaminodiphenyl ether, 3,4′-diaminodiphenyl ether, 1,4-bis(4-aminophenoxy)benzene, 1,3-bis(aminomethyl)benzene, 1,3-bis(4-aminophenoxy)benzene, 1,3-bis(3-aminophenoxy)benzene, 1,4-diaminobenzene, 1,3-diaminobenzene, 2,4-diaminotoluene, and 4,4′-diaminodiphenylmethane; 4,4′-diaminodiphenyl sulfone; 3,3′-diaminodiphenyl sulfone; 4,4-diaminobenzophenone; 4,4-diaminodiphenyl sulfide; and 2,2-bis[4-(4-aminophenoxy)phenyl]propane. Among these, from the viewpoint of obtaining a cured product having a lower tensile elastic modulus, aliphatic diamines having 6 to 12 carbon atoms such as 1,6-hexamethylenediamine; diaminocyclohexanes such as 1,4-diaminocyclohexane; and aromatic diamines containing an aliphatic structure having 1 to 4 carbon atoms in an aromatic skeleton such as 2,2-bis[4-(4-aminophenoxy)phenyl]propane are more preferable. Further, when the bismaleimide compound (I) according to the present invention is obtained using these organic diamines (B), one kind of these organic diamines (B) may be used alone or two or more kinds thereof may be used in combination.

A method of reacting the dimer acid-derived diamine (A), the tetracarboxylic dianhydride (C) having an alicyclic structure, and the maleic anhydride, or a method of reacting the dimer acid-derived diamine (A), the organic diamine (B), the tetracarboxylic dianhydride (C) having an alicyclic structure, and the maleic anhydride is not particularly limited, and a known method is appropriately adopted. For example, first, the dimer acid-derived diamine (A), the tetracarboxylic dianhydride (C), and, if necessary, the organic diamine (B) are stirred in a solvent such as toluene, xylene, tetralin, N,N-dimethylacetamide, or N-methyl-2-pyrrolidone or a mixed solvent thereof at room temperature (about 23° C.) for 30 to 60 minutes to synthesize a polyamic acid, then maleic anhydride is added to the obtained polyamic acid, and the mixture is stirred at room temperature (about 23° C.) for 30 to 60 minutes to synthesize a polyamic acid with maleic acid added to both ends. A solvent that forms an azeotrope with water, such as toluene, is further added to this polyamic acid, and the mixture is refluxed at a temperature of 100 to 160° C. for 3 to 6 hours while removing water generated in the progress of imidation, whereby the desired bismaleimide compound can be obtained. In such a method, a catalyst such as pyridine or methanesulfonic acid may be further added.

The mixing ratio of the raw materials in the reaction is preferably determined such that (Total number of moles of all diamines contained in dimer acid-derived diamine (A) and organic diamine (B)):(Total number of moles of tetracarboxylic dianhydride (C) having an alicyclic structure+One half of number of moles of maleic anhydride) is 1:1. Further, when the organic diamine (B) is used, flexibility derived from the dimer acid is exhibited, and a cured product having a lower elastic modulus tends to be obtained. From such a viewpoint, (Number of moles of organic diamine(B))/(Number of moles of all diamines contained in dimer acid-derived diamine (A)) is preferably 1 or less, and more preferably 0.4 or less. When the organic diamine (B) is used, the polymerization form of the amic acid unit composed of the dimer acid-derived diamine (A) and the tetracarboxylic dianhydride (C) having an alicyclic structure, with the amic acid unit composed of the organic diamine (B) and the tetracarboxylic dianhydride (C) having an alicyclic structure may be random polymerization or block polymerization.

The bismaleimide compound (I) thus obtained is preferably a bismaleimide compound (I) represented by the following general formula (1):

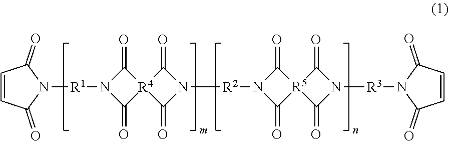

wherein R¹ represents a divalent hydrocarbon group (a) derived from a dimer acid, R² represents a divalent organic group (b) other than the divalent hydrocarbon group (a) derived from the dimer acid, R³ represents any one selected from the group consisting of the divalent hydrocarbon group (a) derived from the dimer acid and the divalent organic group (b) other than the divalent hydrocarbon group (a) derived from the dimer acid, and R⁴ and R⁵ represent each independently one or more organic groups selected from a tetravalent organic group having 4 to 40 carbon atoms (preferably 6 to 40 carbon atoms) which has a monocyclic or condensed polycyclic alicyclic structure, a tetravalent organic group having 8 to 40 carbon atoms in which organic groups each having a monocyclic alicyclic structure are linked to each other directly or via a crosslinking structure, and a tetravalent organic group having 8 to 40 carbon atoms which has a semi-alicyclic structure having both an alicyclic structure and an aromatic ring; m is an integer of 1 to 30, n is an integer of 0 to 30, and R⁴ and R⁵ may be the same or different from each other.

The divalent hydrocarbon group (a) derived from the dimer acid in the formula (1) is as described above. Further, in the present invention, the divalent organic group (b) other than the divalent hydrocarbon group (a) derived from the dimer acid in the formula (1) refers to a divalent residue obtained by removing two amino groups from the organic diamine (B). However, in the same compound, the divalent hydrocarbon group (a) derived from the dimer acid and the divalent organic group (b) are not the same. Furthermore, the tetravalent organic group in the formula (1) refers to a tetravalent residue obtained by removing two groups represented by —CO—O—CO— from the tetracarboxylic dianhydride.

In the formula (1), m is the number of repeating unit (hereinafter, sometimes referred to as dimer acid-derived structure) containing the divalent hydrocarbon group (a) derived from the dimer acid, and represents an integer of 1 to 30. When the value of m exceeds the upper limit, the solubility in a solvent tends to decrease, and in particular, the solubility in a developing solution during development, which will be described later, tends to decrease. Further, the value of m is particularly preferably 3 to 10 from the viewpoint that the solubility in the developing solution during development becomes preferable.

In the formula (1), n is the number of repeating unit (hereinafter, sometimes referred to as organic diamine-derived structure) containing the divalent organic group (b), and represents an integer of 0 to 30. When the value of n exceeds the upper limit, the flexibility of the obtained cured product deteriorates, and the resin tends to be hard and brittle. Further, the value of n is particularly preferably 0 to 10 from the viewpoint that a cured product having a low elastic modulus tends to be obtained.

In addition, when m in the formula (1) is 2 or more, R¹ and R⁴ may be the same or different between the respective repeating units. Moreover, when n in the formula (1) is 2 or more, R² and R⁵ may be the same or different between the respective repeating units. Furthermore, as the bismaleimide compound represented by the formula (1), the dimer acid-derived structure and the organic diamine-derived structure may be random or block.

Moreover, in the case where the bismaleimide compound (I) according to the present invention is obtained from the dimer acid-derived diamine (A), the maleic anhydride, the tetracarboxylic dianhydride (C) and, if necessary, the organic diamine (B), when the reaction rate is 100%, the n and m can be represented by the mixed molar ratios of the all diamines contained in the dimer acid-derived diamine (A), the organic diamine (B), the maleic anhydride, and the tetracarboxylic dianhydride (C). That is, (m+n):(m+n+2) is represented by (Total number of moles of all diamines contained in the dimer acid-derived diamine (A) and organic diamine (B)):(Total number of moles of maleic anhydride and tetracarboxylic dianhydride (C)). M:n is represented by (Number of moles of all diamines contained in dimer acid-derived diamine (A)):(Number of moles of organic diamine (B)), and 2: (m+n) is represented by (Number of moles of maleic anhydride):(Number of moles of tetracarboxylic dianhydride (C)).

Furthermore, in the bismaleimide compound (I) according to the present invention, the sum of m and n (m+n) is preferably 2 to 30 from the viewpoint that a cured product having a lower elastic modulus tends to be obtained. The ratio of m and n (n/m) is preferably 1 or less and more preferably 0.4 or less from the viewpoint that flexibility derived from the dimer acid is exhibited and a cured product having a lower elastic modulus tends to be obtained.

As the bismaleimide compound (I) according to the present invention, one kind thereof may be used alone or two or more kinds thereof may be used in combination.

### <Photopolymerization Initiator (II)>

The photopolymerization initiator (II) according to the present invention is not particularly limited, and conventionally used ones can be appropriately adopted. Examples thereof include photopolymerization initiators such as acetophenone, 2,2-dimethoxyacetophenone, p-dimethylaminoacetophenone, Michler's ketone, benzyl, benzoin, benzoin methyl ether, benzoin ethyl ether, benzoin isopropyl ether, benzoin n-propyl ether, benzoin isopropyl ether, benzoin n-butyl ether, benzyl dimethyl ketal, thioxanthone, 2-chlorothioxanthone, 2-methylthioxanthone, 2,2-dimethoxy-1,2-diphenylethan-1-one, 1-hydroxy-cyclohexyl-phenyl-ketone, 2-hydroxy-2-methyl-1-phenyl-propan-1-one, 1-[4-(2-hydroxyethoxy)-phenyl]-2-hydroxy-2-methyl-1-propan-1-one, 2-hydroxy-1-{4-[4-(2-hydroxy-2-methyl-propionyl)-benzyl]phenyl}-2-methyl-propan-1-one, 2-methyl-1-(4-methylthiophenyl)-2-morpholinopropan-1-one, 2-benzyl-2-dimethylamino-1-(4-morpholinophenyl)-1-butanone, 2,4,6-trimethylbenzoyl-diphenyl-phosphine oxide, bis(2,4,6-trimethylbenzoyl)-phenylphosphine oxide, 1,2-octanedione,1-[4-(phenylthio)-,2-(O-benzoyloxime)], ethanone,1-[9-ethyl-6-(2-methylbenzoyl)-9H-carbazole-3-yl]-,1-(O-acetyloxime), and 2,4-dimethylthioxanthone. As such a photopolymerization initiator (II), one kind thereof may be used alone or two or more kinds thereof may be used in combination.

Among these, as the photopolymerization initiator (II) according to the present invention, from the viewpoint of being capable of forming a fine pattern using a reduction projection exposure machine (stepper; light source wavelength: 365 nm, 436 nm), which is standardly used in the manufacturing process of a semiconductor protective film or the like, it is preferable to use one that efficiently generates radicals at an exposure wavelength of 310 to 436 nm (more preferably 365 nm). Further, the maleimide group generally does not undergo homopolymerization by the action of radicals, and the dimerization reaction of the bismaleimide compound proceeds mainly through the reaction with radicals generated from the photopolymerization initiator to form a crosslinked structure. Therefore, the present inventors presume that the bismaleimide compound is apparently less reactive as compared with an acrylic compound or the like generally used as a photopolymerizable compound. Accordingly, from the viewpoint that radicals can be generated more efficiently and the reactivity at an exposure wavelength of 310 to 436 nm (more preferably 365 nm) is increased, the photopolymerization initiator (II) according to the present invention is more preferably a compound having an oxime structure or a thioxanthone structure.

Examples of such a photopolymerization initiator (II) include 1,2-octanedione,1-[4-(phenylthio)-,2-(O-benzoyloxime)] (manufactured by BASF Japan, “IRGACURE OXE-01”), ethanone,1-[9-ethyl-6-(2-methylbenzoyl)-9H-carbazole-3-yl]-,1-(O-acetyloxime) (manufactured by BASF Japan, “IRGACURE OXE-02”), having an oxime structure, 2,4-dimethylthioxanthone (manufactured by Nippon Kayaku Co., Ltd., “DETX-S”) having a thioxanthone structure. Such a photopolymerization initiator having a high ability to generate radicals by light tends to have too high reactivity when used for photopolymerization of an ordinary acrylic compound or the like and it tends to be difficult to control the reaction. However, the initiator can be preferably used in the present invention.

### <Photosensitive Resin Composition>

The photosensitive resin composition of the present invention contains the bismaleimide compound (I) and the photopolymerization initiator (II). In the photosensitive resin composition of the present invention, the content of the photopolymerization initiator (II) is preferably 0.1 to 15 parts by mass, and more preferably 0.5 to 5 parts by mass with respect to 100 parts by mass of the bismaleimide compound (I). When the content is less than 0.1 parts by mass, the dimerization reaction by light irradiation does not proceed sufficiently during exposure, and the polymerized film tends to peel off from the inorganic surface protective film during development. On the other hand, when the content exceeds 15 parts by mass, the reaction proceeds too much and the polymerization reaction at an unexposed part proceeds, so that it tends to be difficult to form a fine pattern.

According to the photosensitive resin composition of the present invention, heat-curing is not required or, even when it is heat-cured as needed, the heat-curing can be performed at a relatively lower temperature than that in convenient cases, and a cured product having a sufficiently small tensile elastic modulus can be obtained. Therefore, the residual stress generated in the film after curing can be sufficiently reduced, and the warpage of a substrate such as a silicon wafer can be sufficiently suppressed. Furthermore, according to the photosensitive resin composition of the present invention, even when the film thickness is 10 μm or more, a fine pattern (preferably an aspect ratio of the opening diameter (Via diameter) of 0.3 or more, more preferably 0.5 or more) can be formed by irradiation with a light of 310 to 436 nm (preferably 365 nm). In the present invention, the aspect ratio of the opening diameter (Via diameter) is a value expressed by the following equation: “Aspect ratio=(Thickness of cured film)/(Opening diameter of through hole formed in cured film)”.

The photosensitive resin composition of the present invention sufficiently contains the bismaleimide compound (I) and the photopolymerization initiator (II) and is not particularly limited, but the photosensitive resin composition is preferably dissolved in an organic solvent. As the organic solvent, there may be mentioned aromatic solvents such as toluene, xylene and tetralin; ketone solvents such as methyl isobutyl ketone, cyclopentanone and cyclohexanone; cyclic ether solvents such as tetrahydroxyfuran; and organic solvents such as methyl benzoate. As these organic solvents, one kind thereof may be used alone or two or more kinds thereof may be used in combination. Further, these organic solvents may contain a solvent such as ethyl lactate, propylene glycol monomethyl ether acetate, or γ-butyrolactone, in which the bismaleimide compound is difficult to dissolve, within the range where the bismaleimide compound (I) does not precipitate. With regard to the concentration at the time of dissolving the bismaleimide compound (I) and the photopolymerization initiator (II) in the organic solvent, from the viewpoint that a suitable viscosity is obtained, the solid content concentration of the photosensitive resin composition is preferably 20 to 70% by mass.

Moreover, the photosensitive resin composition of the present invention may further contain a sensitizer. As the sensitizer, 4,4′-bis(diethylamino)benzophenone and the like may be mentioned. When the sensitizer is contained in the present invention, the content thereof is preferably 0.01 to 2 parts by mass and more preferably 0.05 to 0.5 parts by mass with respect to 100 parts by mass of the bismaleimide compound (I). By incorporating such a sensitizer, the sensitivity of the photosensitive resin composition to light can be further increased.

The photosensitive resin composition of the present invention may further contain a polymerizable compound. The polymerizable compound refers to a compound having a polymerizable functional group such as an acryl group, a methacryl group, an allyl group, or a styryl group. The polymerizable compound may be a compound having a plurality of the polymerizable functional groups. By incorporating the polymerizable compound, the sensitivity of the photosensitive resin composition to light can be further increased. As the polymerizable compound, an acrylate is preferable from the viewpoint that a crosslinking reaction through photopolymerization is more likely to occur. As the acrylate, there may be mentioned hydrogenated dicyclopentadienyl diacrylate, dicyclopentenyl acrylate, dicyclopentenyloxyethyl acrylate, 1,3-butanediol diacrylate, 1,4-butanediol diacrylate, 1,6-butanediol diacrylate, diethylene glycol diacrylate, neopentyl glycol diacrylate, polyethylene glycol 200 diacrylate, polyethylene glycol 400 diacrylate, polyethylene glycol 600 diacrylate, diethylene glycol diacrylate, neopentyl glycol diacrylate, hydroxypivalic acid ester neopentyl glycol diacrylate, triethylene glycol diacrylate, bis(acryloxyethoxy) bisphenol A, bis(acryloxyethoxy) tetrabromobisphenol A, tripropylene glycol diacrylate, trimethylolpropane triacrylate, pentaerythritol triacrylate, tris(2-hydroxyethyl) isocyanate, pentaerythritol tetraacrylate, dipentaerythritol hexaacrylate, dipentaerythritol monohydroxy pentaacrylate, and the like.

When the polymerizable compound is incorporated, the content thereof is preferably 30 parts by mass or less with respect to 100 parts by mass of the bismaleimide compound (I). When the content of the polymerizable compound exceeds 30 parts by mass, the crosslinking reaction through photopolymerization of the polymerizable compound alone proceeds, and the tensile elastic modulus of the obtained cured product tends to increase. Further, since the polymerizable compound is highly reactive with radicals, it tends to be difficult to control the reaction when a highly reactive photopolymerization initiator such as a photopolymerization initiator having at least one structure selected from the group consisting of an oxime structure and a thioxanthone structure preferably used in the present invention. In general, when a polymerizable compound is added, the tensile elastic modulus of the obtained cured product tends to increase and the flexibility tends to be impaired. However, in the case of the bismaleimide compound (I) according to the present invention, the tensile elastic modulus is unlikely to be high and the flexibility is not easily impaired in the obtained cured product even when a polymerizable compound is added. The present inventors presume that this is because the bismaleimide compound (I) according to the present invention has a reactive maleimide group only at both ends and does not have a crosslinkable reactive group in the molecular chain. Moreover, the photosensitive resin composition of the present invention may further contain a leveling agent, an antifoaming agent, and the like within the range where the advantageous effects of the present invention are not impaired.

The photosensitive resin composition of the present invention can be used by a commonly known using method. For example, a support is first coated with the photosensitive resin composition of the present invention whose viscosity has been adjusted with the organic solvent, and then the composition is dried at 50 to 180° C., preferably 80 to 140° C. for 5 to 30 minutes, whereby a film-like photosensitive resin composition can be formed. Examples of the support include a silicon wafer, a ceramic substrate, a rigid substrate, a flexible substrate, and a silicon wafer on which an inorganic surface protective film such as a SiN film or a SiO₂ film is formed. According to the present invention, even when a silicon wafer having the inorganic surface protective film formed thereon is used as a support, a cured product having excellent close adhesion (adhesiveness) to the inorganic surface protective film can be obtained.

The coating method is not particularly limited, and there may be mentioned coating using a spin coater, a slit coater, a roll coater, or the like, screen printing, and the like. Among these, for example, as a coating method for a silicon wafer, a coating method using a spin coater is preferably adopted. The film thickness of the film-like photosensitive resin composition can be arbitrarily adjusted by adjusting the concentration of the photosensitive resin composition and the coating thickness, and is not particularly limited. For example, in the case of a protective film for a semiconductor element or an interlayer insulating film, the film thickness after drying is preferably 3 to 50 μm, more preferably 5 to 30 μm, and even more preferably 5 to 20 μm. When the film thickness is less than 3 μm, it tends to be impossible to sufficiently protect the elements and circuits under the film, while when the thickness exceeds 50 μm, it tends to be difficult to form a fine pattern. In the present invention, even when the film thickness is 10 μm or more (preferably 10 to 20 μm), a fine pattern can be formed, and it is possible to form such a pattern that the aspect ratio of the opening diameter (Via diameter) of the through hole formed by the exposure and development to be described later is 0.3 or more (more preferably 0.5 or more).

Next, the film-like photosensitive resin composition thus obtained is exposed with applying a mask having a predetermined pattern shape to effect photopolymerization of the photosensitive resin composition of the present invention. As an exposure method, contact exposure or reduction projection exposure may be mentioned. The exposure wavelength is preferably ultraviolet light to visible light having a wavelength of 200 to 500 nm, and a standard reduction projection exposure machine (stepper) can be used. Further, from the viewpoint of being able to form a fine pattern, the exposure wavelength is more preferably 310 to 436 nm, and more preferably 365 nm. The exposure amount is not particularly limited but, in the present invention, it is preferably 300 to 2000 mJ/cm² and more preferably 500 to 1500 mJ/cm², because a fine pattern can be formed even at a relatively low exposure amount and a large exposure amount is not required.

Then, a polymer film (polymer) having a predetermined pattern can be obtained by performing development where the unexposed portion of the film-like photosensitive resin composition after the exposure is dissolved and removed with a developing solution. That is, in the exposed portion, radicals generated from the photopolymerization initiator by light irradiation react with the maleimide group, crosslinking is achieved between the bismaleimide compounds (I) mainly by the dimerization reaction, and the portion becomes insoluble in the developing solution. On the other hand, since the unexposed portion dissolves in the developing solution, a polymer film having a pattern such as a through hole having a predetermined opening diameter (Via diameter) can be obtained by utilizing the difference in solubility in the developing solution between the exposed portion and the unexposed portion. As the developing solution, there may be mentioned aromatic solvents such as toluene and xylene; cyclic ketone solvents such as cyclopentanone and cyclohexanone; cyclic ether solvents such as tetrahydroxyfuran: and mixed solvents thereof. Moreover, the developing solution may further contain an alcohol solvent such as methanol, ethanol and propanol, in order to adjust the solubility at the time of development. As the developing method, a method such as a spraying method, a paddle method, or a dipping method may be mentioned.

The polymer film having a predetermined pattern obtained by the development is preferably further rinsed with an organic solvent such as cyclopentanone or a mixed solvent of cyclopentanone and ethanol. The polymer film after development preferably has a residual film ratio of 90% or more from the viewpoint of suppressing the occurrence of surface roughness and facilitating dimensional design. In the present invention, the residual film ratio refers to the ratio of the film thickness of the polymer film after development to the film thickness of the film-like photosensitive resin composition after drying (before exposure) (Film thickness of polymer film after development/Film thickness of film-like photosensitive resin composition after drying (before exposure)).

Next, a cured film (cured product) having a predetermined pattern can be obtained by heating and curing the polymer film having a predetermined pattern obtained by the development, if necessary. The heating temperature (curing temperature) is preferably 60 to 230° C., and more preferably 150 to 230° C. The heating time is preferably 30 to 120 minutes. In the present invention, the curing temperature refers to a temperature required for heat-curing of the maleimide group, which remains unreacted at the time of exposure, by a thermal reaction. The maleimide group that has been unreacted in the above-mentioned photopolymerization is crosslinked by such a heat-curing reaction, but when the photosensitive resin composition of the present invention is used, it is not necessary to raise the curing temperature unlike the cases of a conventional polyimide precursor or polybenzoxazole precursor. This is because a dehydration ring-closure reaction is not necessary in the case of the bismaleimide compound (I) according to the present invention.

As described above, by using the photosensitive resin composition of the present invention, a cured film having a fine pattern can be obtained. As the pattern, the aspect ratio of the opening diameter (Via diameter) of the formed through hole is preferably 0.3 or more, and more preferably 0.5 or more. In the present invention, the opening diameter can be determined by the measurement with an optical microscope or a scanning electron microscope (SEM).

Further, in the cured film obtained by using the photosensitive resin composition of the present invention, the tensile elastic modulus is preferably 50 to 800 MPa, more preferably 50 to 500 MPa, further preferably 100 to 500 MPa, and still further preferably 100 to 300 MPa. Thus, the cured product obtained by using the photosensitive resin composition of the present invention has a sufficiently low curing temperature and a sufficiently low tensile elastic modulus, so that a substrate such as a silicon wafer does not warp and handling ability in subsequent steps is excellent. In the present invention, the tensile elastic modulus can be determined by the measurement with TENSILON (tensile tester) under the conditions of a temperature of 23° C. and a tensile speed of 5 mm/min.

Further, in the cured film obtained by using the photosensitive resin composition of the present invention, the elongation at break is preferably 20 to 200%, and more preferably 70% or more, from the viewpoint of suppressing cracking. In the present invention, the elongation at break can be determined by the measurement with TENSILON (tensile tester) under the conditions of a temperature of 23° C. and a tensile speed of 5 mm/min.

As described above, the photosensitive resin composition of the present invention can be heat-cured at a relatively low temperature and can form a fine pattern at a low exposure amount as compared with conventional cases, and can afford a cured product having a sufficiently small tensile elastic modulus and exhibiting an excellent adhesion to an inorganic surface protective film or a metal wiring material. Further, even in the case of heat-curing, it is possible to perform the heat-curing at a relatively low temperature as compared with conventional cases, and a cured film having a sufficiently small tensile elastic modulus can be obtained. Therefore, the residual stress generated in the film after curing can be made sufficiently small, and the warpage of a substrate such as a silicon wafer can be sufficiently suppressed. Furthermore, according to the present invention, it is possible to form a fine pattern even at an exposure wavelength of 310 to 436 nm (preferably 365 nm) and a low exposure amount of 2000 mJ/cm² or less, and it is possible to form such a pattern that the aspect ratio of the opening diameter (Via diameter) of the through hole is 0.3 or more (more preferably 0.5 or more). The present inventors presume that this is because, since the photosensitive resin composition of the present invention absorbs little at 365 nm and the reaction of the maleimide group is mainly a dimerization reaction, the progress of the polymerization into an unexposed portion by a chain reaction as in the case of an acrylic compound is suppressed.

The cured product after photo-curing or photo- and heat-curing (curing in which photo-curing and heat-curing are used in combination) obtained by using the photosensitive resin composition of the present invention can be suitably used for at least one kind of film selected from the group consisting of a surface protective film of a semiconductor element, an interlayer insulating film, and an insulating film of a rewiring layer. Further, the photosensitive resin composition of the present invention is particularly effective when a film thickness of 10 μm or more is needed and such patterning that the aspect ratio of the opening diameter (Via diameter) of the through hole is 0.3 or more (more preferably 0.5 or more) is required.

In the above, the bismaleimide compound and the photosensitive resin composition according to the present invention have been described in detail. The present inventors presume the reasons why the object of the present invention is achieved by the photosensitive resin composition and the like of the present invention as follows. That is, since a conventional maleimide compound generally undergoes mainly a dimerization reaction in a photopolymerization reaction, the efficiency of the crosslinking reaction tends to be low as compared with the case of an acrylic compound that is another photopolymerizable compound. Therefore, the present inventors presume that a very large exposure amount is required for sufficiently forming the crosslinked structure by photopolymerization. Further, conventionally, a maleimide compound is mainly used as a heat-polymerizable compound from the reasons that the photoreaction of the compound itself proceeds only at a wavelength of 310 nm or less and it is difficult to cause chain polymerization by radicals, for example. On the other hand, since the specific bismaleimide compound according to the present invention has a structure having a flexible skeleton containing a structure derived from a dimer acid, when such a bismaleimide compound is combined with, for example, a photopolymerization initiator that generates radicals, the maleimide groups are likely to be adjacent to each other and the efficiency of the crosslinking reaction is improved. Thus, it is presumed that, according to the photosensitive resin composition of the present invention, a fine pattern can be formed at a relatively low exposure amount, conventional heat-curing at a high temperature is not required, and a cured product having a sufficiently small tensile elastic modulus and exhibiting an excellent adhesion to the adherend can be obtained.

As described above, the present inventors presume that the cured product obtained from the photosensitive resin composition of the present invention exhibits an excellent adhesion to an adherend, particularly an inorganic surface protective film or a metal wiring material because the cured product can sufficiently adhere to the adherend owing to a sufficiently small tensile elastic modulus and thereby interaction with the inorganic surface protective film or the metal wiring material is also generated.

Further, since the photosensitive resin composition of the present invention absorbs little at 365 nm, the present inventors presume that, even when the film thickness is 10 μm or more, a fine pattern can be formed using a reduction projection exposure machine that is standardly used in the manufacturing process of a semiconductor protective film or the like.

### EXAMPLES

Hereinafter, the present invention will be described in more detail based on Examples and Comparative Examples, but the present invention is not limited to the following Examples. The patterning performance evaluation and the mechanical property evaluation in each of Examples and Comparative Examples were performed as follows. The measurement conditions for molecular weight are as follows.

Model: GPC TOSOH HLC-8220GPC

Column: Super HZM-N

Eluent: THF (tetrahydrofuran); 0.35 ml/min, 40° C.

Detector: RI (differential refractometer)

Molecular weight standard: Polystyrene

### Synthesis Example 1 (I-1)

Into a 500 ml round-bottom flask equipped with a fluororesin-coated stirring bar were charged 110 g of toluene and 36 g of N-methylpyrrolidone. Next, 88.0 g (0.16 mol) of PRIAMINE 1074 (manufactured by Croda Japan K.K.) was added, and then 15.8 g (0.16 mol) of methanesulfonic anhydride was slowly added to form a salt. The whole was stirred and mixed for approximately 10 minutes, and then 5-(2,5-dioxotetrahydrofuryl)-3-methyl-3-cyclohexene-1,2-dicarboxylic dianhydride (21.8 g, 0.08 mol) was slowly added to the stirred mixture. A Dean-Stark trap and a condenser were attached to the flask. The mixture was heated to reflux for 6 hours to form an amine-terminated diimide. The theoretical amount of water produced from this condensation was obtained by this time. The reaction mixture was cooled to room temperature or lower, and 19.4 g (0.20 mol) of maleic anhydride was added to the flask. The mixture was refluxed for another 8 hours to give the expected amount of produced water. After cooling to room temperature, 200 ml of toluene was further added to the flask. Next, the diluted organic layer was washed with water (100 ml×3 times) to remove salts and unreacted raw materials. Then, the solvent was removed under vacuum to obtain 120 g (yield 95%, Mw=3,200) of an amber-colored wax-like bismaleimide compound (I-1).

### Synthesis Example 2 (I-2)

Into a 500 ml round-bottom flask equipped with a fluororesin-coated stirring bar were charged 110 g of toluene and 36 g of N-methylpyrrolidone. Next, 90.5 g (0.17 mol) of PRIAMINE 1074 (manufactured by Croda Japan K.K.) was added, and then 16.3 g (0.17 mol) of methanesulfonic anhydride was slowly added to form a salt. The whole was stirred and mixed for approximately 10 minutes, and then 1,2,4,5-cyclohexanetetracarboxylic dianhydride (18.9 g, 0.08 mol) was slowly added to the stirred mixture. A Dean-Stark trap and a condenser were attached to the flask. The mixture was heated to reflux for 6 hours to form an amine-terminated diimide. The theoretical amount of water produced from this condensation was obtained by this time. The reaction mixture was cooled to room temperature or lower, and 19.9 g (0.20 mol) of maleic anhydride was added to the flask. The mixture was refluxed for another 8 hours to give the expected amount of produced water. After cooling to room temperature, 200 ml of toluene was further added to the flask. Next, the diluted organic layer was washed with water (100 ml×3 times) to remove salts and unreacted raw materials. Then, the solvent was removed under vacuum to obtain 110 g (yield 92%, Mw=3,000) of an amber-colored wax-like bismaleimide compound (I-2).

### Synthesis Example 3 (I-3)

Into a 500 ml round-bottom flask equipped with a fluororesin-coated stirring bar were charged 110 g of toluene and 36 g of N-methylpyrrolidone. Next, 85.6 g (0.16 mol) of PRIAMINE 1074 (manufactured by Croda Japan K.K.) was added, and then 15.4 g (0.16 mol) of methanesulfonic anhydride was slowly added to form a salt. The whole was stirred and mixed for approximately 10 minutes, and then 1,1′-bicyclohexane-3,3′,4,4′-tetracarboxylic 3,4:3′,4′-dianhydride (24.5 g, 0.08 mol) was slowly added to the stirred mixture. A Dean-Stark trap and a condenser were attached to the flask. The mixture was heated to reflux for 6 hours to form an amine-terminated diimide. The theoretical amount of water produced from this condensation was obtained by this time. The reaction mixture was cooled to room temperature or lower, and 18.8 g (0.19 mol) of maleic anhydride was added to the flask. The mixture was refluxed for another 8 hours to give the expected amount of produced water. After cooling to room temperature, 200 ml of toluene was further added to the flask. Next, the diluted organic layer was washed with water (100 ml×3 times) to remove salts and unreacted raw materials. Then, the solvent was removed under vacuum to obtain 108 g (yield 90%, Mw=3,600) of an amber-colored wax-like bismaleimide compound (I-3).

### Synthesis Example 4 (I-4)

Into a 500 ml round-bottom flask equipped with a fluororesin-coated stirring bar were charged 110 g of toluene and 36 g of N-methylpyrrolidone. Next, 85.9 g (0.16 mol) of PRIAMINE 1074 (manufactured by Croda Japan K.K.) was added, and then 15.5 g (0.16 mol) of methanesulfonic anhydride was slowly added to form a salt. The whole was stirred and mixed for approximately 10 minutes, and then 4-(2,5-dioxotetrahydrofuran-3-yl)-1,2,3,4-tetrahydronaphthlene-1,2-dicarboxylic anhydride (24.1 g, 0.08 mol) was slowly added to the stirred mixture. A Dean-Stark trap and a condenser were attached to the flask. The mixture was heated to reflux for 6 hours to form an amine-terminated diimide. The theoretical amount of water produced from this condensation was obtained by this time. The reaction mixture was cooled to room temperature or lower, and 18.9 g (0.19 mol) of maleic anhydride was added to the flask. The mixture was refluxed for another 8 hours to give the expected amount of produced water. After cooling to room temperature, 200 ml of toluene was further added to the flask. Next, the diluted organic layer was washed with water (100 ml×3 times) to remove salts and unreacted raw materials. Then, the solvent was removed under vacuum to obtain 106 g (yield 89%, Mw=3,700) of a dark amber-colored wax-like bismaleimide compound (I-4).

### Synthesis Example 5 (I-5)

Into a 500 ml round-bottom flask equipped with a fluororesin-coated stirring bar were charged 110 g of toluene and 36 g of N-methylpyrrolidone. Next, 73.5 g (0.14 mol) of PRIAMINE 1074 (manufactured by Croda Japan K.K.) and 8.4 g (0.06 mol) of 1,3-bis(aminomethyl)cyclohexane were added, and then 18.9 g (0.20 mol) of methanesulfonic anhydride was slowly added to form a salt. The whole was stirred and mixed for approximately 10 minutes, and then 5-(2,5-dioxotetrahydrofuryl)-3-methyl-3-cyclohexene-1,2-dicarboxylic dianhydride (26.0 g, 0.10 mol) was slowly added to the stirred mixture. A Dean-Stark trap and a condenser were attached to the flask. The mixture was heated to reflux for 6 hours to form an amine-terminated diimide. The theoretical amount of water produced from this condensation was obtained by this time. The reaction mixture was cooled to room temperature or lower, and 23.1 g (0.24 mol) of maleic anhydride was added to the flask. The mixture was refluxed for another 8 hours to give the expected amount of produced water. After cooling to room temperature, 200 ml of toluene was further added to the flask. Next, the diluted organic layer was washed with water (100 ml×3 times) to remove salts and unreacted raw materials. Then, the solvent was removed under vacuum to obtain 108 g (yield 90%, Mw=2,800) of an amber-colored wax-like bismaleimide compound (I-5).

### Comparative Synthesis Example 1

Into a 500 ml round-bottom flask equipped with a fluororesin-coated stirring bar were charged 110 g of toluene and 36 g of N-methylpyrrolidone. Next, 90.9 g (0.17 mol) of PRIAMINE 1074 (manufactured by Croda Japan K.K.) was added, and then 16.4 g (0.17 mol) of methanesulfonic anhydride was slowly added to form a salt. The whole was stirred and mixed for approximately 10 minutes, and then pyromellitic anhydride (18.6 g, 0.08 mol) was slowly added to the stirred mixture. A Dean-Stark trap and a condenser were attached to the flask. The mixture was heated to reflux for 6 hours to form an amine-terminated diimide. The theoretical amount of water produced from this condensation was obtained by this time. The reaction mixture was cooled to room temperature or lower, and 20.0 g (0.20 mol) of maleic anhydride was added to the flask. The mixture was refluxed for another 8 hours to give the expected amount of produced water. After cooling to room temperature, 200 ml of toluene was further added to the flask. Next, the diluted organic layer was washed with water (100 ml×3 times) to remove salts and unreacted raw materials. Then, the solvent was removed under vacuum to obtain 102 g (yield 85%, Mw=3,800) of a brown wax-like bismaleimide compound.

The bismaleimide compound of Comparative Synthesis Example 1 is easily available as “BMI-3000” from DESIGNER MOLECURES Inc.

### Comparative Synthesis Example 2

Into a 500 ml round-bottom flask equipped with a fluororesin-coated stirring bar were charged 110 g of toluene and 36 g of N-methylpyrrolidone. Next, 85.3 g (0.16 mol) of PRIAMINE 1074 (manufactured by Croda Japan K.K.) was added, and then 15.4 g (0.16 mol) of methanesulfonic anhydride was slowly added to form a salt. The whole was stirred and mixed for approximately 10 minutes, and then 4,4′-oxydiphthalic dianhydride (24.8 g, 0.08 mol) was slowly added to the stirred mixture. A Dean-Stark trap and a condenser were attached to the flask. The mixture was heated to reflux for 6 hours to form an amine-terminated diimide. The theoretical amount of water produced from this condensation was obtained by this time. The reaction mixture was cooled to room temperature or lower, and 18.8 g (0.19 mol) of maleic anhydride was added to the flask. The mixture was refluxed for another 8 hours to give the expected amount of produced water. After cooling to room temperature, 200 ml of toluene was further added to the flask. Next, the diluted organic layer was washed with water (100 ml×3 times) to remove salts and unreacted raw materials. Then, the solvent was removed under vacuum to obtain 106 g (yield 88%, Mw=3,700) of a brown wax-like bismaleimide compound.

The bismaleimide compound of Comparative Synthesis Example 2 is easily available as “BMI-1500” from DESIGNER MOLECURES Inc.

### Comparative Synthesis Example 3

Into a 500 ml round-bottom flask equipped with a fluororesin-coated stirring bar were charged 110 g of toluene and 36 g of N-methylpyrrolidone. Next, 90.9 g (0.17 mol) of PRIAMINE 1074 (manufactured by Croda Japan K.K.) was added, and then 16.4 g (0.17 mol) of methanesulfonic anhydride was slowly added to form a salt. The whole was stirred and mixed for approximately 10 minutes, and then pyromellitic anhydride (18.6 g, 0.08 mol) was slowly added to the stirred mixture. A Dean-Stark trap and a condenser were attached to the flask. The mixture was heated to reflux for 6 hours to form an amine-terminated diimide. The theoretical amount of water produced from this condensation was obtained by this time. After cooling to room temperature, 200 ml of toluene was further added to the flask. Next, the diluted organic layer was washed with water (100 ml×3 times) to remove salts and unreacted raw materials. Then, the solvent was removed under vacuum to obtain 90.4 g (yield 85%, Mw=3,600) of a brown wax-like polyimide compound.

The materials used in the present Examples are shown.

### [Component (I); Bismaleimide Compound]

I: the bismaleimide compounds shown in Synthesis Examples (I-1) to (I-5), and the bismaleimide compounds and the polyimide compound shown in Comparative Synthesis Examples 1 to 3.

### [Component (II); Photopolymerization Initiator]

II-1: ethanone,1-[9-ethyl-6-(2-methylbenzoyl)-9H-carbazol-3-yl]-,1-(O-acetyloxime) (manufactured by BASF Japan, “IRGACURE OXE-02”)

II-2: 2,4-dimethylthioxanthone (manufactured by Nippon Kayaku Co., Ltd., “DETX-S”)

### Examples 1 to 5 and Comparative Examples 1 to 3

Ingredients (I) to (II) of the blending amounts (parts by mass) shown in Table 1 and 50 parts by mass of cyclopentanone as a solvent were blended to prepare photosensitive resin compositions of Examples 1 to 5 and Comparative Examples 1 to 3.

### <Evaluation of Photosensitive Resin Compositions>

The photosensitive resin compositions of Examples 1 to 5 and Comparative Examples 1 to 3 were evaluated as shown below. The results are summarized in Table 1.

TABLE 1

| | | Example | | | | | Comparative Example | | |
|---|---|---|---|---|---|---|---|---|---|
| Component | Material | 1 | 2 | 3 | 4 | 5 | 1 | 2 | 3 |
| (I) | I-1 | 50 | | | | | | | |
| Bismaleimide | I-2 | | 50 | | | | | | |
| compound | I-3 | | | 50 | | | | | |
| | I-4 | | | | 50 | | | | |
| | I-5 | | | | | 50 | | | |
| | Comparative | | | | | | 50 | | |
| | Synthesis Example 1 | | | | | | | | |
| | Comparative | | | | | | | 50 | |
| | Synthesis Example 2 | | | | | | | | |
| | Comparative Synthesis | | | | | | | | 50 |
| | Example 3 | | | | | | | | |
| (II) Photo- | II-1 | 3 | 3 | 3 | 3 | 3 | 3 | 3 | 3 |
| polymerization | II-2 | 1 | 1 | 1 | 1 | 1 | 1 | 1 | 1 |
| initiator | | | | | | | | | |
| Solvent | Cyclopentanone | 50 | 50 | 50 | 50 | 50 | 50 | 50 | 50 |
| Patterning | Sensitivity (mJ/cm²) | 800 | 1000 | 800 | 1500 | 1200 | 3000 | 3000 | 3000 < *1 |
| performance | Residual film ratio (%) | 94 | 92 | 94 | 90 | 91 | 85 | 82 | 0 |
| | Resolution (μm) | 30 | 30 | 30 | 30 | 30 | 50 | 50 | −*2 |
| | Development residue | ◯ | ◯ | ◯ | ◯ | ◯ | ◯ | ◯ | −*2 |
| Dielectric | Dk | 2.2 | 2.2 | 2.2 | 2.3 | 2.3 | 2.4 | 2.4 | −*2 |
| properties | Df | 0.0020 | 0.0021 | 0.0024 | 0.0023 | 0.0028 | 0.0035 | 0.0040 | −*2 |
| Mechanical | Tensile elastic | 120 | 160 | 110 | 220 | 260 | 450 | 360 | −*2 |
| properties | modulus (MPa) | | | | | | | | |
| | Elongation at break (%) | 116 | 106 | 120 | 98 | 85 | 53 | 57 | −*2 |
| Insulation | Water absorption (%) | 0.3 | 0.3 | 0.4 | 0.5 | 0.4 | 0.5 | 1.3 | −*2 |
| reliability | HAST resistance | ◯ | ◯ | ◯ | ◯ | ◯ | Δ | Δ | X |

*1: A cured film could not be obtained at 3000 mJ/cm².
*2: Not measured because a cured film could not be obtained.

### (Sensitivity, Residual Film Ratio, Resolution, Development Residue)

The photosensitive resin compositions obtained in each of Examples 1 to 5 and Comparative Examples 1 to 3 was spin-coated on a silicon substrate and heated at 120° C. for 4 minutes to form a coating film having a film thickness of 10 to 15 μm. Next, using an “ultra-high pressure mercury lamp 500W multi-light” manufactured by USHIO, reduction projection exposure was performed with i-line (365 nm) through a mask having square hole patterns from 1 μm in length and 1 μm in width to 100 μm in length and 100 vim in width. The exposure amount was changed from 500 to 3000 mJ/cm² by 100 mJ/cm². After exposure, it was developed with cyclopentanone. The sensitivity was an exposure amount at which the residual film ratio began to be constant. The residual film ratio was calculated according to the following formula.

Residual film ratio (%)=(Film thickness of coating film after development/Film thickness of coating film before development)×100

The residual film ratio in Table 1 is the residual film ratio at the sensitivity shown in Table 1.

In addition, the smallest opening width among the open square hole patterns was used as an index of resolution. With regard to the sensitivity and the resolution, the smaller, the better. The results are shown in Table 1.

Furthermore, when the patterns after development were observed on a microscope, the case where a residue was found in all or a part of the pattern openings was evaluated as x in the item of development residue. The case without residue was marked as 0.

Thereafter, the resist pattern was heat-treated (cured) in nitrogen at a temperature of 180° C. for 60 minutes.

### (Evaluation of Mechanical Properties)

First, the photosensitive resin composition obtained in each of Examples and Comparative Examples was applied on a copper foil having a thickness of 12 μm using a spin coater, and then dried at a temperature of 100° C. for 10 minutes to form a film-like photosensitive resin composition on the copper foil. The coating thickness of the photosensitive resin composition was adjusted so that the film thickness of the film-like photosensitive resin composition after drying was 10 μm. This film-like photosensitive resin composition is exposed to a light having a wavelength of 365 mu at an exposure amount of 2000 mJ/cm² using an “ultra-high pressure mercury lamp 500W multi-light” manufactured by USHIO, and then heated at a temperature of 180° C. for 60 minutes to achieve curing. Thereafter, the copper foil was removed by etching to obtain a cured film.

Next, the obtained cured film was cut to a length of 10 mm, and at a temperature of 23° C., the elongation at break (%) and the tensile elastic modulus (MPa) were measured and determined under the condition of a tensile speed of 5 mm/min, using TENSILON (tensile tester).

### (Evaluation of Dielectric Properties (Dielectric Constant: Dk, Dielectric Loss Tangent: Df))

For evaluation of dielectric properties, varnish was coated on a copper foil with a desktop coater so that the thickness after drying was 50 μm, and dried to obtain a resin film (semi-cured). Next, the obtained resin film (semi-cured) was irradiated with UV at 2000 mJ/cm². A resin film was similarly formed and laminated on the produced resin film, and the film thickness of the resin film was controlled to 300 μm. Furthermore, the copper foil as a support was removed by physical peeling or etching to obtain a resin film for evaluation.

Then, the resin film cut into a length of 60 mm, a width of 2 mm, and a thickness of 0.3 mm was used as a test piece and dielectric properties were measured by a cavity resonator perturbation method. A vector-type network analyzer ADMSO10c1 manufactured by AET, Inc. was used as the measuring instrument, and CP531 (10 GHz band resonator) manufactured by Kanto Electronic Application and Development Inc. was used as the cavity resonator. The conditions were a frequency of 10 GHz and a measuring temperature of 25° C.

### (Measurement of Water Absorption)

Using a bar coder, varnish was applied to a tin-free steel at a thickness of 200 μm and dried at 90° C. for 5 minutes to form a resin layer. A sample (cured product) was prepared by exposing at 2000 mJ/cm² to achieve curing, and then heating at 180° C. for 1 hour. The cured film was immersed in water at 25° C. for 24 hours and taken out from the water, water was wiped off well, and the amount of water in the cured film was calculated by the Karl Fischer method.

### (Hast Resistance)

Each composition was applied on ESPANEX M series, where a comb-shaped pattern of L/S=10 μm/10 μm was formed (manufactured by Nippon Steel Chemical: base imide thickness of 25 μm and Cu thickness of 18 μm), by a screen printing method so that the thickness was 25 microns, and the coating film was dried in a hot air dryer at 80° C. for 60 minutes. Next, a test substrate for HAST evaluation was obtained by exposing at 2000 mJ/cm² using an ultraviolet exposure apparatus (manufactured by USHIO: 500 W multi-light) to achieve curing, and then heating at 180° C. for 1 hour. The electrode part of the obtained substrate was subjected to wiring connection with solder, the substrate was placed in an environment of 130° C. and 85% RH, a voltage of 5.5 V was applied, and the time until the resistance value became 1×10⁸Ω or less was measured.

O . . . 300 hours or more
Δ . . . 30 to 300 hours
x . . . 30 hours or less

As is clear from the results shown in Table 1, when the photosensitive resin compositions of the present invention obtained in Examples 1 to 5 were used, it was confirmed that a sufficiently small opening diameter was obtained even at a low exposure amount and a fine pattern can be formed. Further, it was confirmed that the photosensitive resin compositions of the present invention obtained in Examples 1 to 5 could afford cured products having a sufficiently small tensile elastic modulus even when they were not subjected to heat-curing at a high temperature and exhibiting an excellent adhesion to an adherend such as an inorganic surface protective film. On the other hand, when the photosensitive resin compositions obtained in Comparative Examples 1 to 3 were used, it was confirmed that an exposure amount of 3000 mJ/cm² was required to form a pattern and it was difficult to apply them as photosensitive resin compositions.

In addition, as is clear from the results shown in Table 1, it was shown that the cured products obtained by using the photosensitive resin compositions of the present invention are excellent maleimide compounds where the photo-curing of the maleimide group sufficiently proceeded even at a low exposure amount and thereby a high insulation reliability could be maintained while maintaining low dielectric properties and water absorption.

The present application is based on a Japanese patent application filed on Apr. 2, 2019 (Japanese Patent Application No. 2019-070316), and the contents of which are incorporated herein by reference.

### INDUSTRIAL APPLICABILITY

As described above, according to the present invention, it is possible to provide a photosensitive resin composition that is capable of forming a fine pattern at a relatively low exposure amount (2000 mJ/cm² or less), does not require conventional heat-curing at a high temperature, and can afford a cured product having a sufficiently small tensile elastic modulus and exhibiting an excellent adhesion to an inorganic surface protective film (silicon nitride film, silicon oxide film, etc.) or a conductive metal wiring material (copper, etc.), a cured product using the same, and a semiconductor element.

In addition, according to the present invention, since heat-curing is not required, or even when heat-curing is performed as needed, heat-curing can be performed at a relatively low temperature (60 to 230° C.) as compared with conventional cases and a cured product having a sufficiently small tensile elastic modulus can be obtained, the residual stress generated in the film after curing can be sufficiently reduced, and the warpage of a silicon wafer can be sufficiently suppressed. Furthermore, according to the present invention, even when the film thickness is large, it is possible to form a fine pattern by irradiation with light at 365 nm. Therefore, such a photosensitive resin composition of the present invention is very useful as a surface protective film of a semiconductor element, an interlayer insulating film, an insulating film of a rewiring layer, and the like.

1. A bismaleimide compound (I) having a cyclic imide bond, which is obtained by a reaction of a diamine (A) derived from a dimer acid, a tetracarboxylic dianhydride (C) having an alicyclic structure, and maleic anhydride.

2. The bismaleimide compound (I) according to claim 1, which is obtained by a reaction of the diamine (A), the tetracarboxylic dianhydride (C), the maleic anhydride, and, in addition, an organic diamine (B) other than the diamine (A) derived from the dimer acid.

3. The bismaleimide compound (I) according to claim 1, wherein the bismaleimide compound (I) is a compound of formula (1): 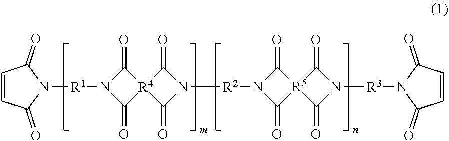
wherein R¹ is a divalent hydrocarbon group (a) derived from a dimer acid, R² is a divalent organic group (b) other than the divalent hydrocarbon group (a) derived from the dimer acid, R³ is any one selected from the group consisting of the divalent hydrocarbon group (a) derived from the dimer acid and the divalent organic group (b) other than the divalent hydrocarbon group (a) derived from the dimer acid, and R⁴ and R⁵ each independently is one or more organic groups selected from a tetravalent organic group having 4 to 40 carbon atoms which has a monocyclic or condensed polycyclic alicyclic structure, a tetravalent organic group having 8 to 40 carbon atoms in which organic groups each having a monocyclic alicyclic structure are linked to each other directly or via a crosslinking structure, and a tetravalent organic group having 8 to 40 carbon atoms which has a semi-alicyclic structure having both an alicyclic structure and an aromatic ring; m is an integer of 1 to 30, n is an integer of 0 to 30, and R⁴ and R⁵ are the same or different from each other.

4. The bismaleimide compound (I) according to claim 1, wherein the tetracarboxylic dianhydride (C) is a compound of formula (2): 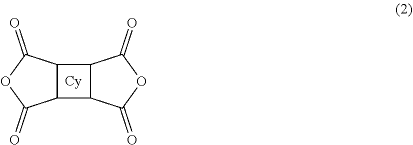
wherein Cy is a tetravalent organic group having 4 to 40 carbon atoms which contains a hydrocarbon ring and the organic group optionally contains an aromatic ring.

5. The bismaleimide compound (I) according to claim 4, wherein the Cy is selected from the group consisting of the formulae (3-1) to (3-11): 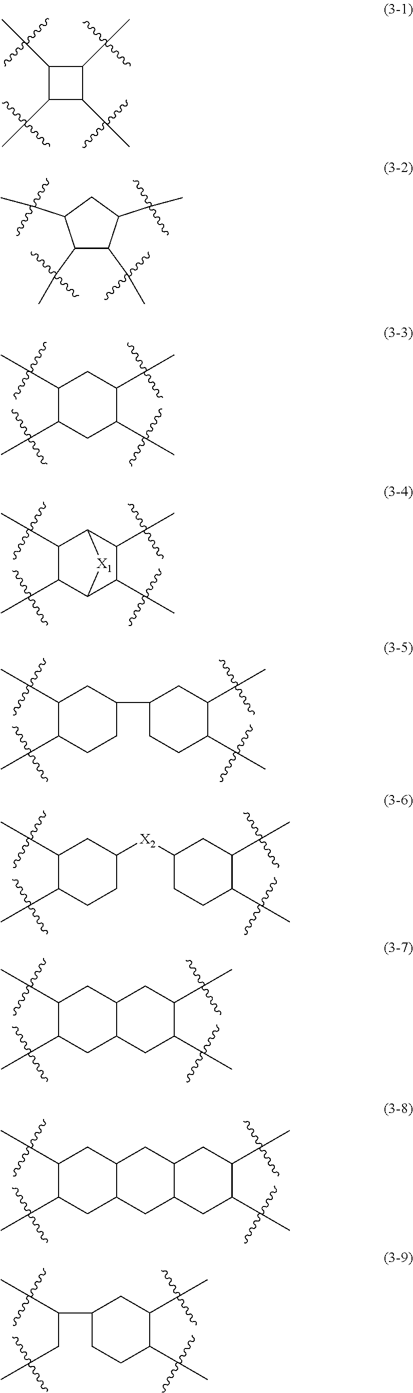 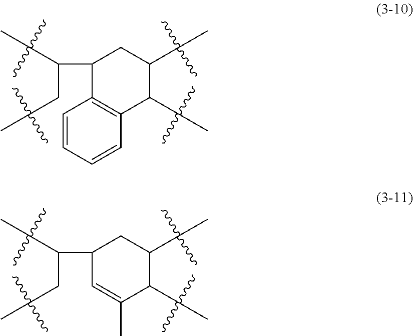 [SMILES: *CC(*)C1CC(*)C(*)c2ccccc21 ; *CC(*)C1C=C(C)C(*)C(*)C1]
wherein:
in the general formula (3-4), X₁ is a direct bond, an oxygen atom, a sulfur atom, a sulfonyl group, or a divalent organic group having 1 to 3 carbon atoms; and
in the general formula (3-6), X₂ is a direct bond, an oxygen atom, a sulfur atom, a sulfonyl group, a divalent organic group having 1 to 3 carbon atoms, or an arylene group.

6. The bismaleimide compound (I) according to claim 1, wherein the tetracarboxylic dianhydride (C) is one or more selected from 1,2,3,4-cyclobutanetetracarboxylic dianhydride (CBDA), 1,2-dimethyl-1,2,3,4-cyclobutanetetracarboxylic dianhydride, 1,2,3,4-tetramethyl-1,2,3,4-cyclobutanetetracarboxylic dianhydride, 1,2,3,4-cyclopentanetetracarboxylic dianhydride, 1,2,4,5-cyclohexanetetracarboxylic dianhydride (H-PMDA), 1,1′-bicyclohexane-3,3′,4,4′-tetracarboxylic-3,4:3′, 4′-dianhydride (H-BPDA), 4-(2,5-dioxotetrahydrofuran-3-yl)-1,2,3,4-tetrahydronaphthalene-1,2-dicarboxylic anhydride, 5-(2, 5-dioxotetrahydrofuryl)-3-methyl-3-cyclohexene-1,2-dicarboxylic anhydride, bicyclo[2.2.2]oct-7-ene-2,3,5,6-tetracarboxylic dianhydride, 2,3,4,5-tetrahydrofuranetetracarboxylic dianhydride, and 3,5,6-tricarboxy-2-norbornaneacetic dianhydride.

7. The bismaleimide compound (I) according to claim 1, wherein the tetracarboxylic dianhydride (C) is a compound of formula (4):

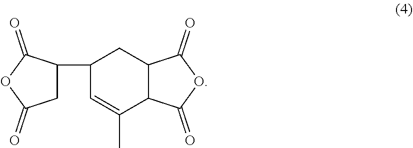 [SMILES: CC1=CC(C2CC(=O)OC2=O)CC2C(=O)OC(=O)C12]

8. The bismaleimide compound (I) according to claim 1, wherein the tetracarboxylic dianhydride (C) is a compound of formula (5):

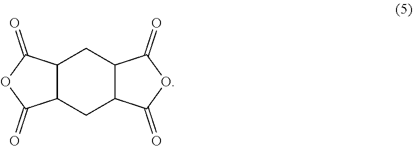 [SMILES: O=C1OC(=O)C2CC3C(=O)OC(=O)C3CC12]

9. The bismaleimide compound (I) according to claim 1, wherein the tetracarboxylic dianhydride (C) is a compound of formula 6:

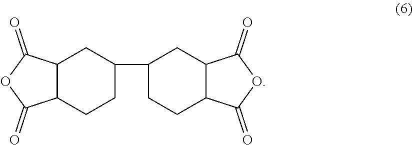 [SMILES: O=C1OC(=O)C2CC(C3CCC4C(=O)OC(=O)C4C3)CCC12]

10. The bismaleimide compound (I) according to claim 1, wherein the tetracarboxylic dianhydride (C) is a compound of formula (7):

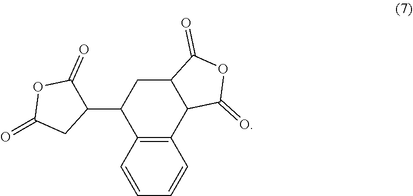 [SMILES: O=C1CC(C2CC3C(=O)OC(=O)C3c3ccccc32)C(=O)O1]

11. A photosensitive resin composition comprising the bismaleimide compound (I) according to claim 1 and a photopolymerization initiator (II), wherein the photopolymerization initiator (II) is a compound having an oxime structure or a thioxanthone structure.

12. The photosensitive resin composition according to claim 11, wherein a content of the photopolymerization initiator (II) is 0.1 to 15 parts by mass with respect to 100 parts by mass of the bismaleimide compound (I).

13. A cured product obtained by photo-curing or photo- and heat-curing of the photosensitive resin composition according to claim 11.

14. A semiconductor element comprising the cured product according to claim 13 as at least one selected from the group consisting of a surface protective film, an interlayer insulating film, and an insulating film of a rewiring layer.
